(19) United States
(12) Patent Application Publication
(10) Pub. No.: US 2016/0013224 A1
(43) Pub. Date: Jan. 14, 2016

(54) PHOTOELECTRIC CONVERSION DEVICE

(71) Applicant: CANON KABUSHIKI KAISHA, Tokyo (JP)

(72) Inventors: Hideshi Kuwabara, Yamato-shi (JP); Mari Isobe, Kawasaki-shi (JP)

(21) Appl. No.: 14/788,880

(22) Filed: Jul. 1, 2015

(30) Foreign Application Priority Data
Jul. 8, 2014 (JP) 2014-140865

(51) Int. Cl. H01L 27/146; H01L 31/0264; H01L 31/0224; H01L 31/02

(52) U.S. Cl. CPC H01L 27/1463; H01L 27/14643; H01L 27/14638; H01L 31/02; H01L 31/0264; H01L 31/0224; H01L 27/14632

(57) ABSTRACT

A photoelectric conversion device includes an element surrounding an active region including first and second areas verging each other at a virtual line, a charge accumulation region arranged in the first area, a floating diffusion region arranged across the first and second areas, a transfer gate electrode, and a first semiconductor region including a portion arranged between the charge accumulation region and the element isolation so as to surround at least part of the charge accumulation region, and a portion arranged in the second area. A width of the second area in a direction parallel to the virtual line is smaller than a width of the first area in the direction.

### BACKGROUND OF THE INVENTION

1. Field of the Invention

The present invention relates to a photoelectric conversion device.

2. Description of the Related Art

FIG. 18 in Japanese Patent Laid-Open No. 2013-225774 shows a solid-state imaging device including a photodiode, a floating diffusion region, and a transfer transistor. The photodiode includes a charge accumulation region formed from an n-layer arranged on a p-type silicon substrate. The floating diffusion region is formed from an n-layer arranged on a p-well arranged on the p-type silicon substrate. The transfer transistor includes, in the p-type silicon layer, a channel which transfers charges from the charge accumulation region to the floating diffusion region. The p-well is not arranged in the region where the channel is formed, and a pixel isolation oxide film (STI) is exposed in the region where the channel is formed. In this arrangement, since the region where the channel is formed has no p-well higher in impurity concentration than the p-type silicon substrate, the transfer efficiency increases at a time of low illuminance (that is, the amount of charges accumulated in the charge accumulation region is small). This improves the linearity between illuminance (incident light amount) and potential change appearing in the floating diffusion region.

In the arrangement disclosed in Japanese Patent Laid-Open No. 2013-225774, however, the pixel isolation oxide film is exposed in the region (p-type semiconductor region) where the channel is formed, and many crystal defects occur in the interface between the region (p-type semiconductor region) where the channel is formed and the pixel isolation oxide film. This tends to result in the generation of a dark current. This dark current changes the potential of the floating diffusion region. That is, the arrangement disclosed in Japanese Patent Laid-Open No. 2013-225774 improves the linearity between illuminance (incident light amount) and potential change appearing in the floating diffusion region but can increase dark current noise.

### SUMMARY OF THE INVENTION

One aspect of the present invention provides a technique advantageous in improving linearity and reducing noise.

One of aspects of the present invention provides a photoelectric conversion device comprising: an element isolation arranged to surround an active region including a first area and a second area which verge each other at a virtual line; a charge accumulation region of a first conductivity type arranged in the first area; a floating diffusion region of the first conductivity type arranged across the first area and the second area; a gate electrode configured to form a channel for transferring charges accumulated in the charge accumulation region to the floating diffusion region; and a first semiconductor region including a portion arranged between the charge accumulation region and the element isolation, so as to surround at least part of the charge accumulation region, and including a portion arranged in the second area, the first semiconductor region having a second conductivity type different from the first conductivity type, wherein a width of the second area in a direction parallel to the virtual line is smaller than a width of the first area in the direction, a boundary line defining an outer edge of the second area includes a first boundary line having a first point on the virtual line as one end and a second point which is not on the virtual line as the other end and a second boundary line having a third point on the virtual line as one end and a fourth point which is not on the virtual line as the other end, the gate electrode includes a first portion spanning the first area and the second area so as to cover the first point, a second portion spanning the first area and the second area so as to cover the third point, and a third portion arranged above the first area so as to connect the first portion to the second portion, and a boundary line defining an outer edge of the first semiconductor region includes a portion passing between the third portion and the virtual line.

Further features of the present invention will become apparent from the following description of exemplary embodiments with reference to the attached drawings.

### BRIEF DESCRIPTION OF THE DRAWINGS

FIG. 1 is a view showing a photoelectric conversion device according to the first embodiment of the present invention;

FIG. 2 is a view showing the photoelectric conversion device according to the first embodiment of the present invention;

FIG. 3A is a view showing an active region;

FIG. 3B is a view showing a gate electrode and a floating diffusion region;

FIG. 4 is a view for explaining a method of manufacturing the photoelectric conversion device according to the first embodiment of the present invention;

FIG. 5 is a view for explaining the method of manufacturing the photoelectric conversion device according to the first embodiment of the present invention;

FIG. 6 is a view for explaining the method of manufacturing the photoelectric conversion device according to the first embodiment of the present invention;

FIG. 7 is a view for explaining the method of manufacturing the photoelectric conversion device according to the first embodiment of the present invention;

FIG. 8 is a view for explaining the method of manufacturing the photoelectric conversion device according to the first embodiment of the present invention;

FIG. 9 is a view for explaining the method of manufacturing the photoelectric conversion device according to the first embodiment of the present invention;

FIG. 10 is a view for explaining the method of manufacturing the photoelectric conversion device according to the first embodiment of the present invention;

FIG. 11 is a view showing a photoelectric conversion device according to the second embodiment of the present invention;

FIG. 12 is a view showing a photoelectric conversion device according to the third embodiment of the present invention;

FIG. 13 is a view showing a photoelectric conversion device according to the fourth embodiment of the present invention;

FIG. 14 is a view showing a photoelectric conversion device according to the fifth embodiment of the present invention;

FIG. 15 is a view showing a photoelectric conversion device according to the sixth embodiment of the present invention;

FIG. 16 is a view showing a photoelectric conversion device according to the seventh embodiment of the present invention;

FIG. 17 is a view showing a photoelectric conversion device according to the eighth embodiment of the present invention;

FIG. 18 is a view showing a photoelectric conversion device according to the ninth embodiment of the present invention;

FIG. 19 is a view showing a photoelectric conversion device according to the 10th embodiment of the present invention;

FIG. 20 is a view showing a photoelectric conversion device according to the 11th embodiment of the present invention;

FIG. 21 is a graph showing linearity at a time of low illuminance in the first embodiment and that in a comparative example; and

FIG. 22 is a view showing the photoelectric conversion device according to the first embodiment of the present invention.

### DESCRIPTION OF THE EMBODIMENTS

The present invention will be described through exemplary embodiments with reference to the accompanying drawings.

The following embodiments each will exemplify a photoelectric conversion device including a single photoelectric conversion unit for the sake of simplicity. Typically, however, a plurality of photoelectric conversion units can be arrayed. A photoelectric conversion device including a plurality of photoelectric conversion units can constitute an AF (Auto Focus) sensor, line sensor, or image sensor. The photoelectric conversion device constitutes part of an imaging device for obtaining an image, for example, a camera.

A p type and an n type to be described below are interchangeable. That is, the p type to be described below can be changed to the n type, and the n type to be described below can be changed to the p type. “First conductivity type” and “second conductivity type” described in the scope of claims mean different conductivity types, which may be the p type and n type, respectively, or may be the n type and p type, respectively. In the following description, signal charges are holes, and become electrons upon interchanging conductivity types.

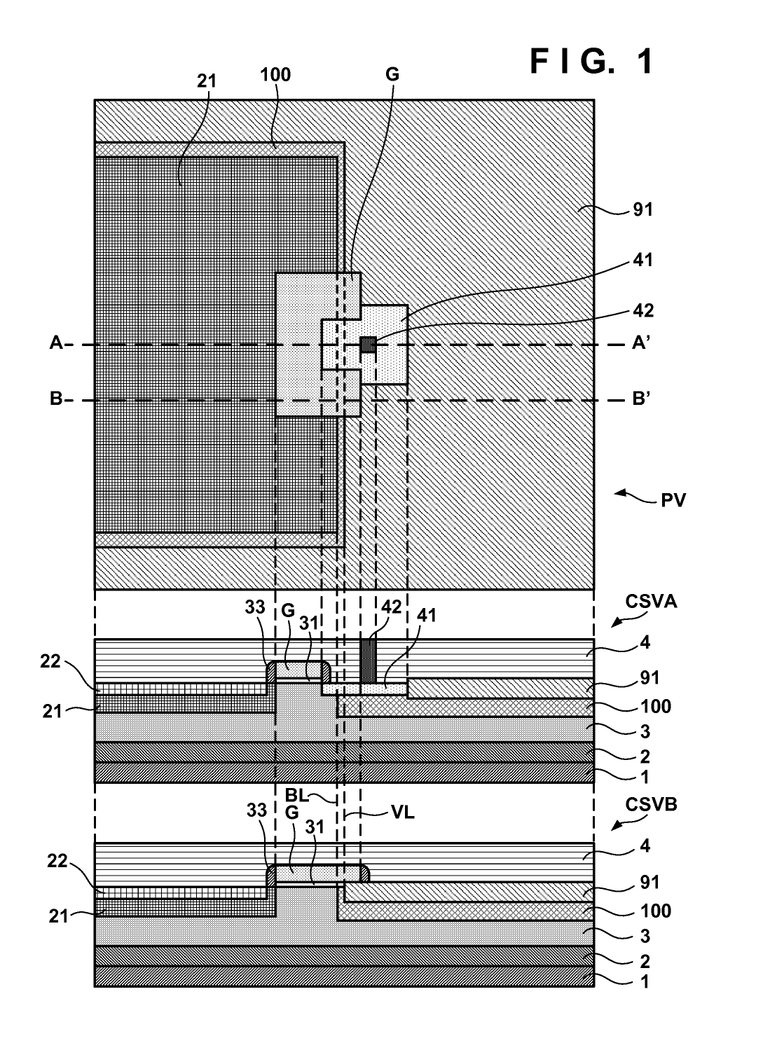

FIG. 1 shows a photoelectric conversion device according to the first embodiment of the present invention. FIG. 1 includes a plan view PV of the photoelectric conversion device, a sectional view CSVA taken along a line A-A′ of the plan view PV, and a sectional view CSVB taken along a line B-B′ of the plan view PV. Note that for the sake of easy understanding of a structure, an interlayer insulating film 4, a third semiconductor region (surface region) 22, and a side spacer 33 are not shown in the plan view PV.

The photoelectric conversion device includes an element isolation 91, a p-type charge accumulation region 21, a p-type floating diffusion region 41, a gate electrode G, and an n-type first semiconductor region 100. The photoelectric conversion device also includes an n-type second semiconductor region 3. The p-type charge accumulation region 21, the p-type floating diffusion region 41, and the n-type first semiconductor region 100 are arranged in the n-type second semiconductor region 3. The n-type impurity concentration in the first semiconductor region 100 is higher than that in the second semiconductor region 3. The second semiconductor region 3 can be, for example, an n-type epitaxial layer. The second semiconductor region 3 can be arranged above, for example, an n-type semiconductor substrate 1 via an n-type buried layer 2 which may be above. The n-type impurity concentration of the buried layer 2 is higher than that of the semiconductor substrate 1 and that of the second semiconductor region 3. The third semiconductor region (surface region) 22 can be arranged on the p-type charge accumulation region 21. An embedded photodiode (photoelectric conversion unit) is constituted by the p-type charge accumulation region 21, a region of the n-type second semiconductor region 3 which is located adjacent to the p-type charge accumulation region 21, and the n-type third semiconductor region 22. The first semiconductor region 100 also exists under the element isolation 91, as shown in sectional view CSVA and the sectional view CSVB.

The gate electrode G is arranged on a gate insulating film 31 on the n-type second semiconductor region 3 to form, in the n-type second semiconductor region 3, a channel for transferring charges accumulated in the p-type charge accumulation region 21 to the p-type floating diffusion region 41 when a predetermined potential is applied to the gate electrode G. The side spacer 33 can be arranged on a side surface of the gate electrode G. The interlayer insulating film 4 covers the gate electrode G, the third semiconductor region 22, the floating diffusion region 41, and the element isolation 91. A contact plug 42 is connected to the floating diffusion region 41. The floating diffusion region 41 can be electrically connected to the gate electrode of an amplifying transistor (not show) via the contact plug 42.

FIG. 1 shows only a portion of the photoelectric conversion unit including the charge accumulation region 21, and the remaining portion may have arbitrary arrangements. For example, the photoelectric conversion unit can have an arrangement like that exemplified in FIG. 22, that is, an arrangement having the first semiconductor region 100 also arranged between the element isolation 91 and a portion of the charge accumulation region 21 which is located on the opposite side to that on which the gate electrode G is arranged.

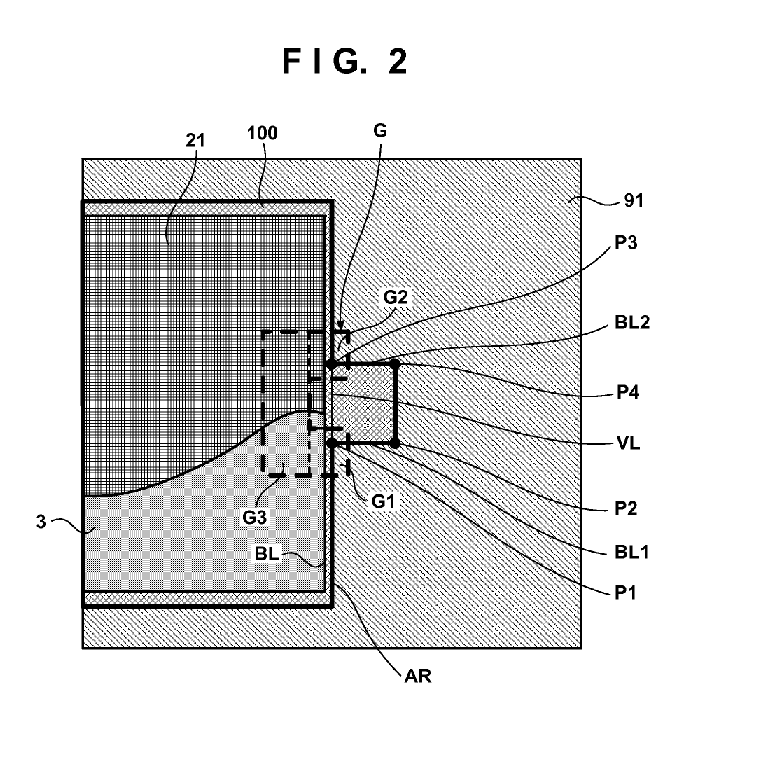

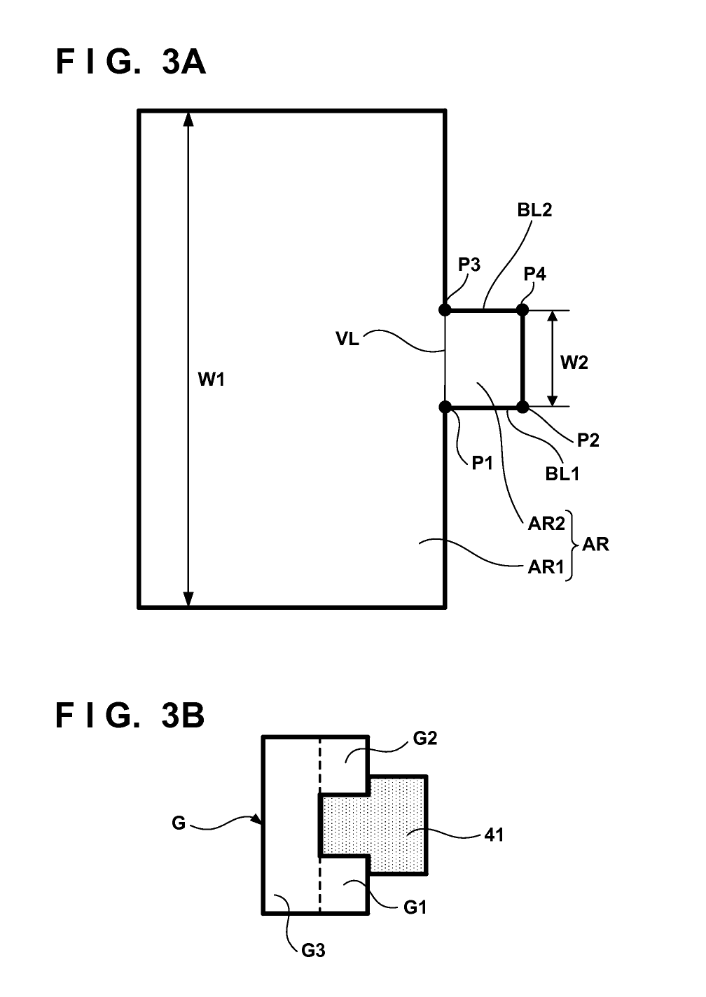

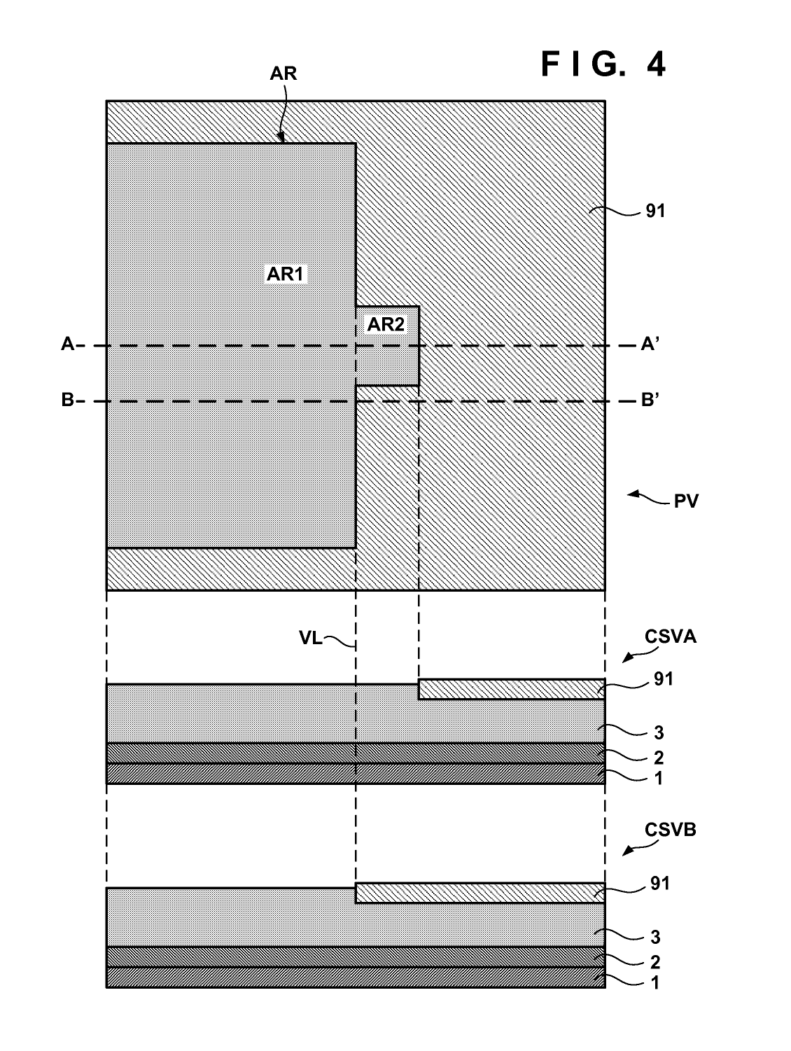

FIG. 2 is a plan view showing the same regions as those in the plan view PV of FIG. 1. Referring to FIG. 2, the gate electrode G is indicated by the dotted line, the third semiconductor region 22 is not shown, part of the charge accumulation region 21 is cut away, and the floating diffusion region 41 is not shown. FIG. 3A shows an active region AR. FIG. 3B shows the gate electrode G and the floating diffusion region 41. In addition, FIGS. 2, 3A, and 3B additionally show lines and points for explaining the structures of the active region AR, the element isolation 91, and the gate electrode G.

On the surface of the structure (semiconductor substrate) existing under the interlayer insulating film 4, the active region AR and the element isolation region where the element isolation 91 is arranged have an exclusive relationship. That is, the region where the element isolation 91 does not exist is the active region AR. The active region AR includes the charge accumulation region 21, the third semiconductor region 22, the floating diffusion region 41, and the first semiconductor region 100.

The element isolation 91 is arranged so as to surround the active region AR. The active region AR includes a first area AR1 and a second area AR2 verging each other at a virtual line VL. The virtual line VL is typically a straight line. If the virtual line VL is a straight line, “virtual line VL” can be replaced with “virtual straight line VL”. As shown in FIG. 3A, a width W2 of the second area AR2 in a direction parallel to the virtual line VL is smaller than the width W1 of the first area AR1 in the direction. As shown in FIGS. 2 and 3A, boundary lines defining the outer edges of the second area AR2 include a first boundary line BL1 and a second boundary line BL2. The first boundary line BL1 is a line having a first point P1 on the virtual line VL as one end and a second point P2 which is not located on the virtual line VL as the other end. The second boundary line BL2 has a third point P3 on the virtual line VL as one end and a fourth point P4 which is not located on the virtual line VL as the other end. In addition, as shown in FIG. 3A, the first area AR1 and the second area AR2 each have a rectangular shape.

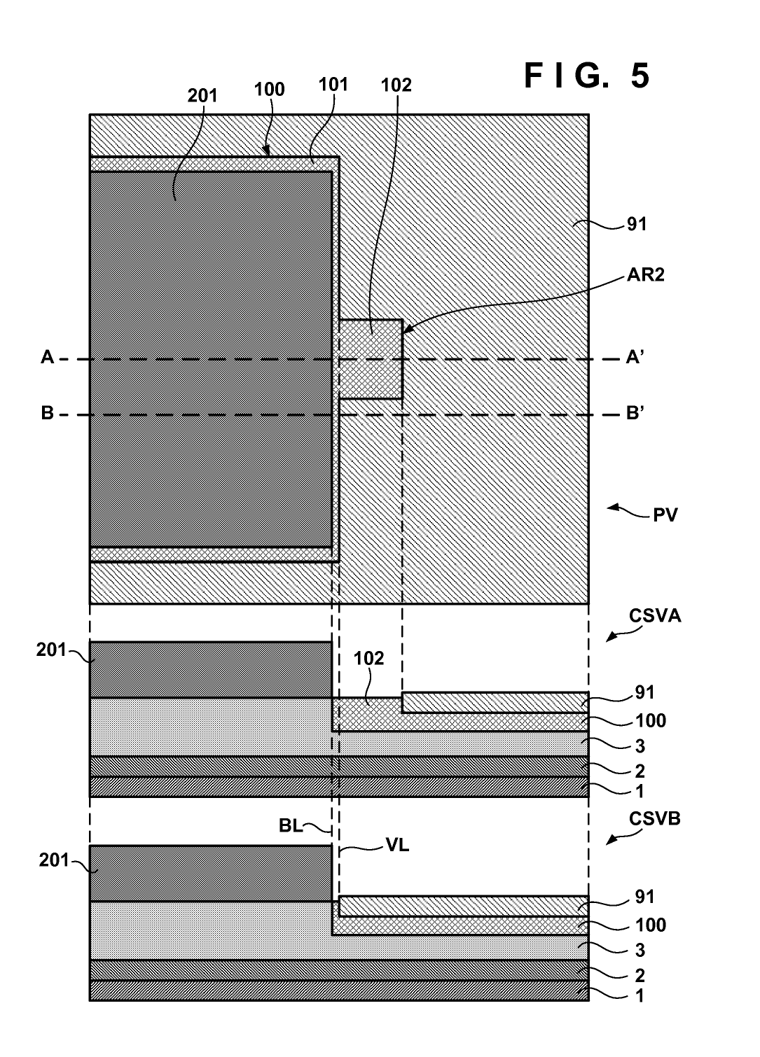

The p-type charge accumulation region 21 is arranged in the first area AR1, and the floating diffusion region 41 is arranged across the first area AR1 and the second area AR2. The n-type first semiconductor region 100 includes a portion (see PV in FIG. 1 and FIG. 2) arranged between the p-type charge accumulation region 21 and the element isolation 91 so as to surround at least part of the p-type charge accumulation region 21. This portion is indicated as a portion 101 in FIG. 5. In addition, the n-type first semiconductor region 100 includes a portion (see CSVA and CSVB in FIG. 1) arranged in the second area AR2 (under the floating diffusion region 41). This portion is indicated as a portion 102 in FIG. 5.

As shown in FIG. 2, the gate electrode G includes a first portion G1, a second portion G2, and a third portion G3. The first portion G1, the second portion G2, and the third portion G3 each can have a rectangular shape. In this case, three sides of the four sides of each rectangular shape can be constituted by sides defining the outer edges of the gate electrode G. The first portion G1 spans the first area AR1 and the second area AR2 so as to cover the first point P1. In addition, the first portion G1 is provided along the first boundary line BL1 (parallel to the first boundary line BL1). The second portion G2 spans the first area AR1 and the second area AR2 so as to cover the third point P3. In addition, the second portion G2 is provided along the second boundary line BL2 (parallel to the second boundary line BL2). The third portion G3 is arranged on the first area AR1 so as to connect the first portion G1 to the second portion G2. A boundary line BL (see FIG. 5) defining an outer edge of the first semiconductor region 100 includes a portion passing between the third portion G3 and the virtual line VL. In an example, the first portion G1 and the second portion G2 extend in a direction perpendicular to the virtual line VL, and the third portion G3 extends in a direction parallel to the virtual line VL.

In the above arrangement, the n-type second semiconductor region 3 where the channel for transferring charges in the charge accumulation region 21 to the floating diffusion region 41 is formed is not in contact with the element isolation 91. In other words, the region of the n-type second semiconductor region 3 where the channel is formed and its adjacent region are not in contact with the element isolation 91. Such an arrangement is effective in reducing the generation of a dark current. In addition, in this arrangement, the n-type first semiconductor region 100 higher in n-type impurity concentration than the n-type second semiconductor region 3 where the channel is formed does not exist under the region where the channel is formed. For this reason, the transfer efficiency at a time of low illuminance (that is, when the amount of charges accumulated in the charge accumulation region is small) increases. This improves the linearity between illuminance (incident light amount) and potential change appearing in the floating diffusion region. In addition, since the gate electrode G includes the first portion G1, the second portion G2, and the third portion G3, it is possible to reduce electric field concentration.

A method of manufacturing the photoelectric conversion device according to the first embodiment will be described below with reference to FIGS. 4 to 10. Note that, like FIG. 1, FIGS. 4 to 10 each also include a plan view PV of the photoelectric conversion device, a sectional view CSVA taken along line A-A′ of the plan view PV, and a sectional view CSVB taken along a line B-B′ of the plan view PV.

First of all, in the step shown in FIG. 4, the element isolation 91 is formed to define the active region AR including the first area AR1 and the second area AR2 in the n-type semiconductor substrate 1 which has the n-type second semiconductor region 3 on the n-type buried layer 2. The element isolation 91 surrounds the active region AR. The element isolation 91 can be constituted by, for example, STI (Shallow Trench Isolation) but may be constituted by LOCOS (LOCal Oxidation of Silicon) or the like. Thereafter, a buffer oxide film (not shown) is formed.

Subsequently, in the step shown in FIG. 5, a resist pattern 201 for forming the n-type first semiconductor region 100 is formed, and an n-type impurity is implanted into the n-type second semiconductor region 3 through an opening of the resist pattern 201 (that is, a region where the resist pattern 201 does not exist), thereby forming the n-type first semiconductor region 100. The n-type first semiconductor region 100 includes the portion 101 arranged between the p-type charge accumulation region 21 and the element isolation 91 so as to surround at least part of the p-type charge accumulation region 21 and the portion 102 arranged in the second area AR2 (under the floating diffusion region 41). The first portion 101 functions as a channel stopper.

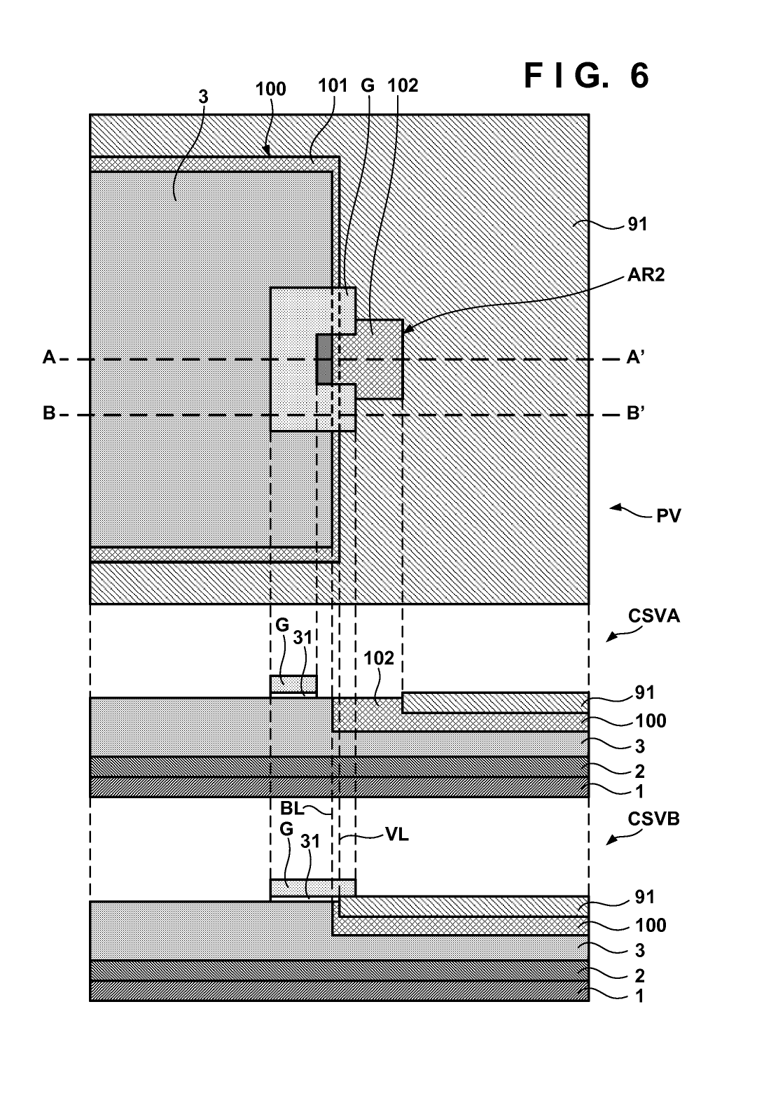

Subsequently, in the step shown in FIG. 6, first of all, the resist pattern 201 and a buffer oxide film are removed. After an oxide film (for example, 7.5 nm thick) and a doped polysilicon film (for example, 250 nm thick) are formed, a resist pattern is formed. The doped polysilicon film is etched, and the resist pattern is removed, thereby forming the gate insulating film 31 and the gate electrode G using the oxide film and the doped polysilicon film.

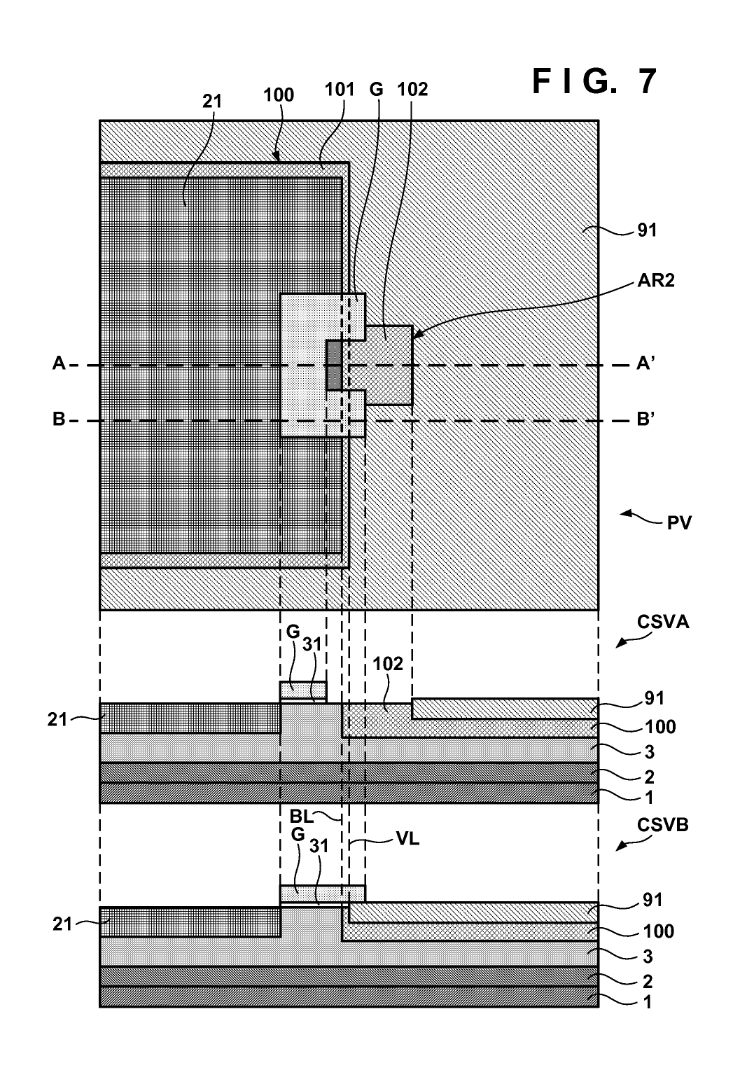

Subsequently, in the step shown in FIG. 7, a resist pattern (not shown) having an opening in a region where the p-type charge accumulation region 21 should be formed is formed, and a p-type impurity is implanted into the n-type second semiconductor region 3 through the opening. This forms the p-type charge accumulation region 21.

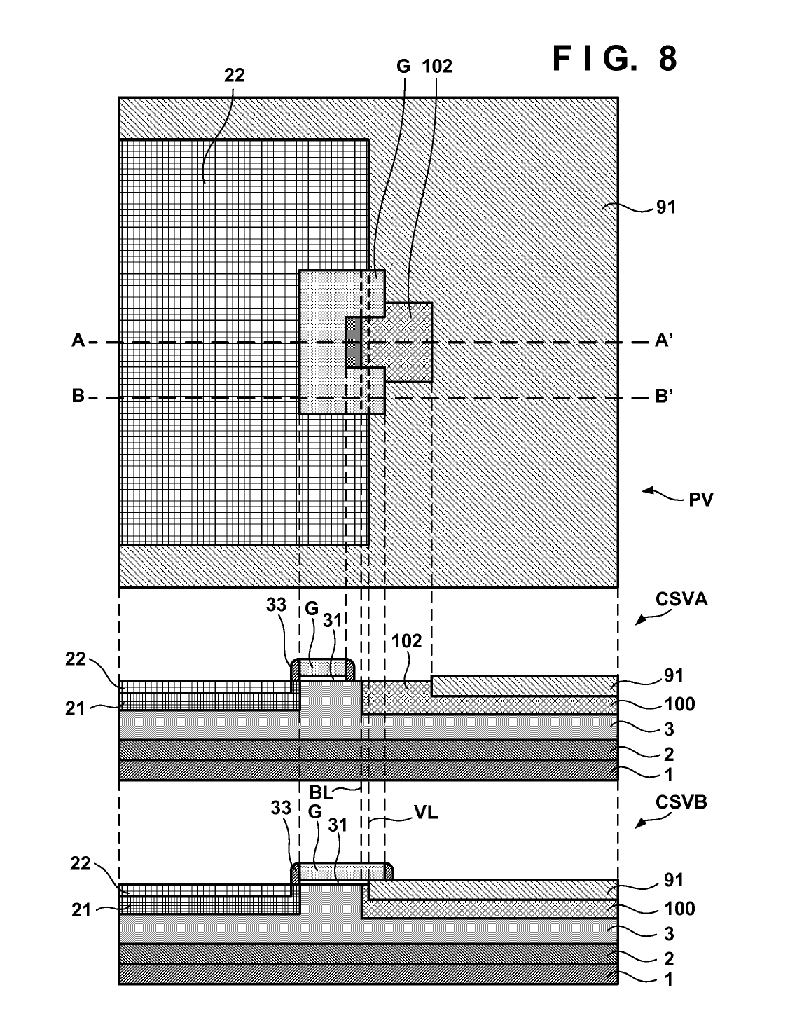

Subsequently, in the step shown in FIG. 8, after the resist pattern formed in the step in FIG. 7 is removed, for example, an oxide film (for example, 120 nm thick) is formed by a low-pressure CVD method or the like. The side spacer 33 is formed by etching back the oxide film. Note that the side spacer 33 is not shown in the plan view PV of FIG. 8. In this case, the oxide film may be a stacked film such as an oxide film/nitride film. In addition, the oxide film may be left on part of the surface of the photoelectric conversion unit (charge accumulation region 21). A buffer oxide film (for example, 10 nm thick) is then formed on the surfaces of the photoelectric conversion unit and the source and drain regions (including a region where the floating diffusion region 41 should be formed) of a MOS transistor. A resist pattern (not shown) having an opening in a region whether the n-type third semiconductor region (surface region) 22 should be formed is formed, and an n-type impurity is implanted into the surface side of the p-type charge accumulation region 21 through the opening. This forms the n-type third semiconductor region (surface region) 22.

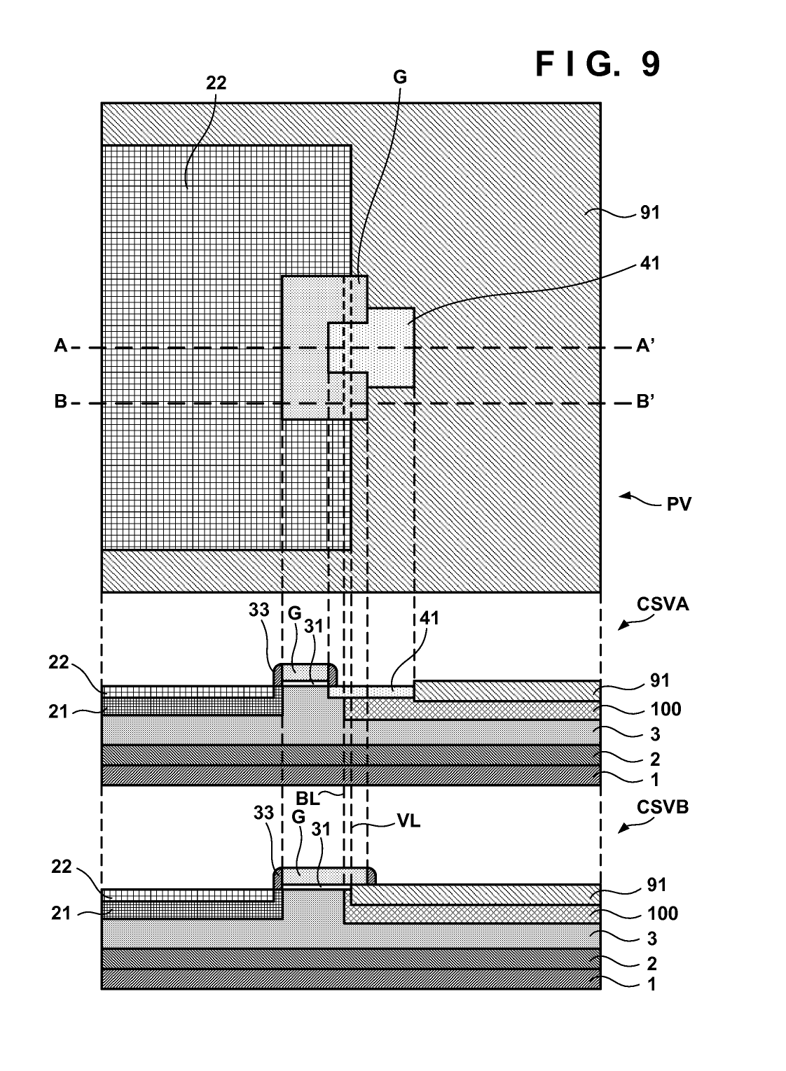

Subsequently, in the step shown in FIG. 9, a resist pattern (not shown) having an opening in a region where the p-type floating diffusion region 41 should be formed is formed, and a p-type impurity is implanted into the region where the p-type floating diffusion region 41 should be formed through the opening. This forms the p-type floating diffusion region 41. In this case, the p-type floating diffusion region 41 can be considered as the drain region of a transfer transistor having the gate electrode G.

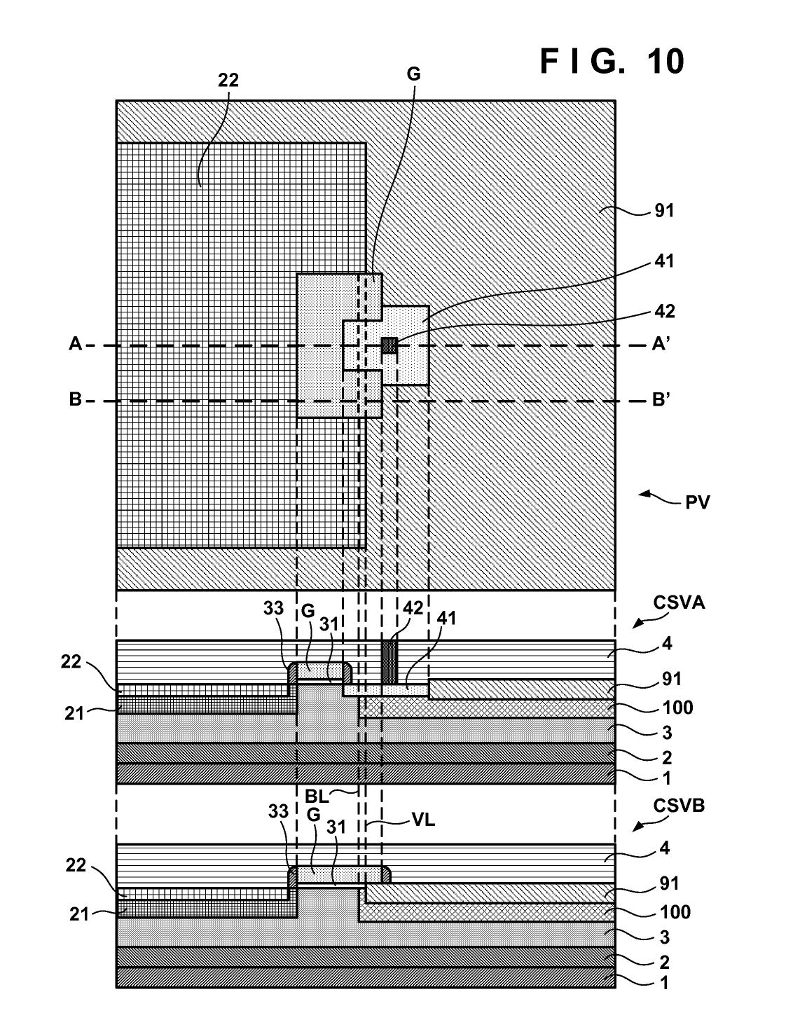

Subsequently, in the step shown in FIG. 10, the interlayer insulating film 4 is formed, and a CMP process is performed to planarize the surface of the interlayer insulating film 4. A contact hole is formed in the surface, and contact ion implantation is performed. Thereafter, a barrier metal (for example, a Ti/TiN film) is formed to form the contact plug 42.

In addition, although not shown, the following is repeated: the formation of a wiring layer, the formation of a resist pattern for a wiring layer, etching, removal of the resist pattern, the formation of an interlayer insulating film, a CMP process, the formation of a resist pattern for a via, etching, and removal of the resist pattern.

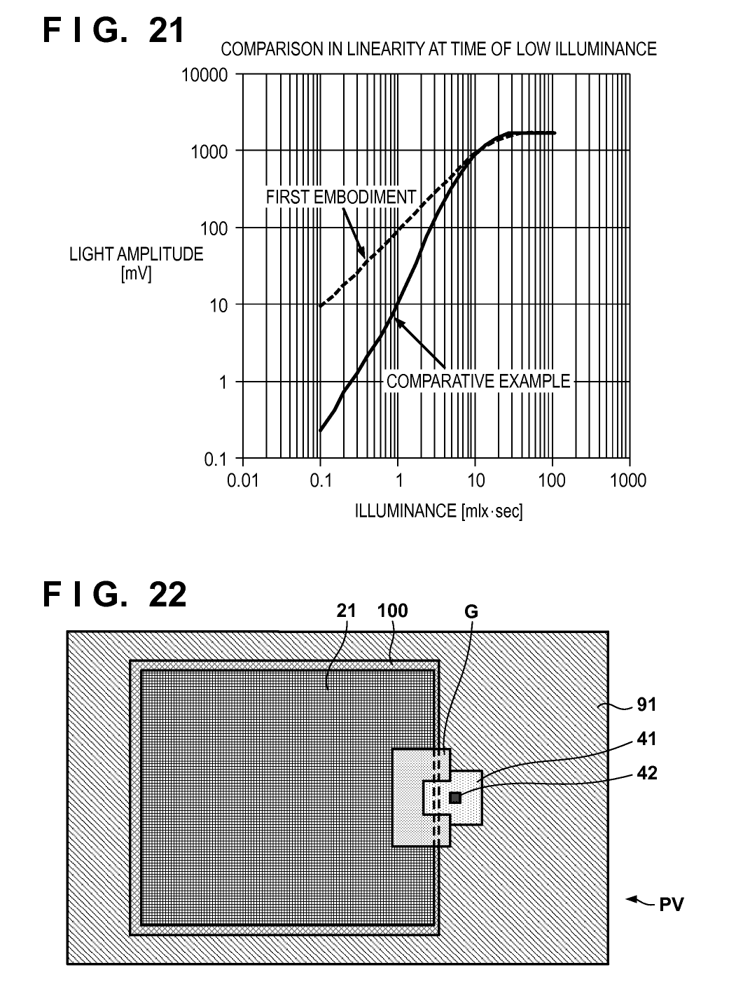

FIG. 21 shows the comparison in linearity at the time of low illuminance between the structure according to the first embodiment, that is, the structure in which the n-type first semiconductor region 100 does not exist under the gate electrode G, and the structure (comparative example) in which the n-type first semiconductor region 100 exists under the gate electrode G. The abscissa represents the illuminance [mlx·sec] of light entering the photoelectric conversion device, and the ordinate represents a potential change [mV] caused by charges transferred to the floating diffusion region. Obviously, the linearity at the time of low illuminance according to the first embodiment is superior to that in the comparative example. In addition, in the first embodiment, the generation of a dark current is reduced.

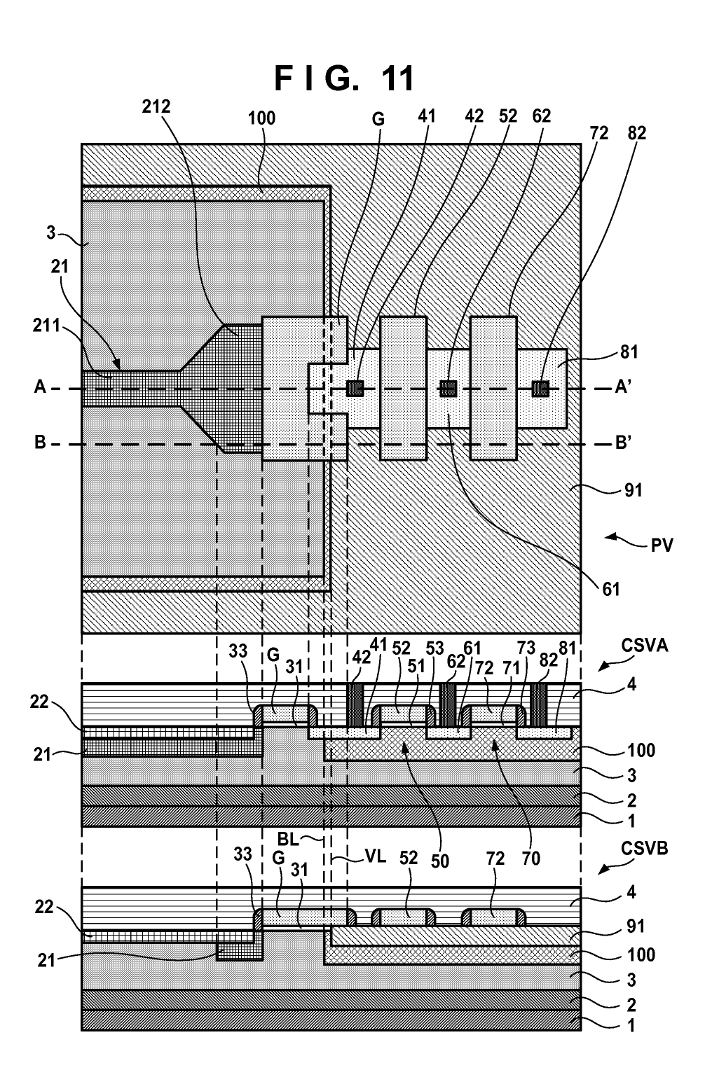

FIG. 11 shows a photoelectric conversion device according to the second embodiment of the present invention. FIG. 11 includes a plan view PV of the photoelectric conversion device, a sectional view CSVA taken along a line A-A′ of the plan view PV, and a sectional view CSVB taken along a line B-B′ line of the plan view PV. Note that for the sake of easy understanding of a structure, an interlayer insulating film 4, a third semiconductor region (surface region) 22, and a side spacer 33 are not shown in the plan view PV in FIG. 11. Note that matters not mentioned in the second embodiment can comply with those in the first embodiment.

In the second embodiment, a p-type charge accumulation region 21 is separated from an n-type first semiconductor region 100 in a direction parallel to a virtual line VL. An n-type second semiconductor region 3 is provided between the p-type charge accumulation region 21 and the n-type first semiconductor region 100. For example, the width of the charge accumulation region 21 in a direction parallel to the virtual line VL is larger than the width of the gate electrode G, within an area of the first area AR1, in a direction parallel to the virtual line VL.

In addition, in the second embodiment, an active region including a p-type floating diffusion region 41 is extended, and a MOS transistor (first transistor) 50 for sensitivity switching and a MOS transistor (second transistor) 70 for resetting are provided. The MOS transistor 50 includes a gate oxide film 51, a gate electrode 52, and a side spacer 53, and forms a channel between the p-type floating diffusion region 41 and a p-type diffusion region 61. The MOS transistor 70 includes a gate oxide film 11, a gate electrode 72, and a side spacer 73, and forms a channel between the p-type diffusion region 61 and a p-type diffusion region 81. Contact plugs 62 and 82 are respectively connected to the diffusion regions 61 and 81.

The diffusion region 61 is connected to one electrode of a capacitor (not shown) via the contact plug 62. When the transfer transistor including the gate electrode G is turned on while the MOS transistor 50 for sensitivity switching is ON, charges in the charge accumulation region 21 are transferred to the capacitance of the floating diffusion region 41 and the capacitance of the capacitor described above. Therefore, a change in the potential of the floating diffusion region 41 caused by the transfer of charges is smaller when the MOS transistor 50 is OFF than when the MOS transistor 50 is ON. That is, the photoelectric conversion device has low sensitivity when the MOS transistor 50 is ON, and has high sensitivity when the MOS transistor 50 is OFF.

The charge accumulation region 21 includes a first accumulation region 211 and a second accumulation region 212 arranged between the first accumulation region 211 and the gate electrode G. In the second embodiment, the width of the first accumulation region 211 in a direction parallel to the virtual line VL is smaller than that of the second accumulation region 212 in the direction parallel to the virtual line VL.

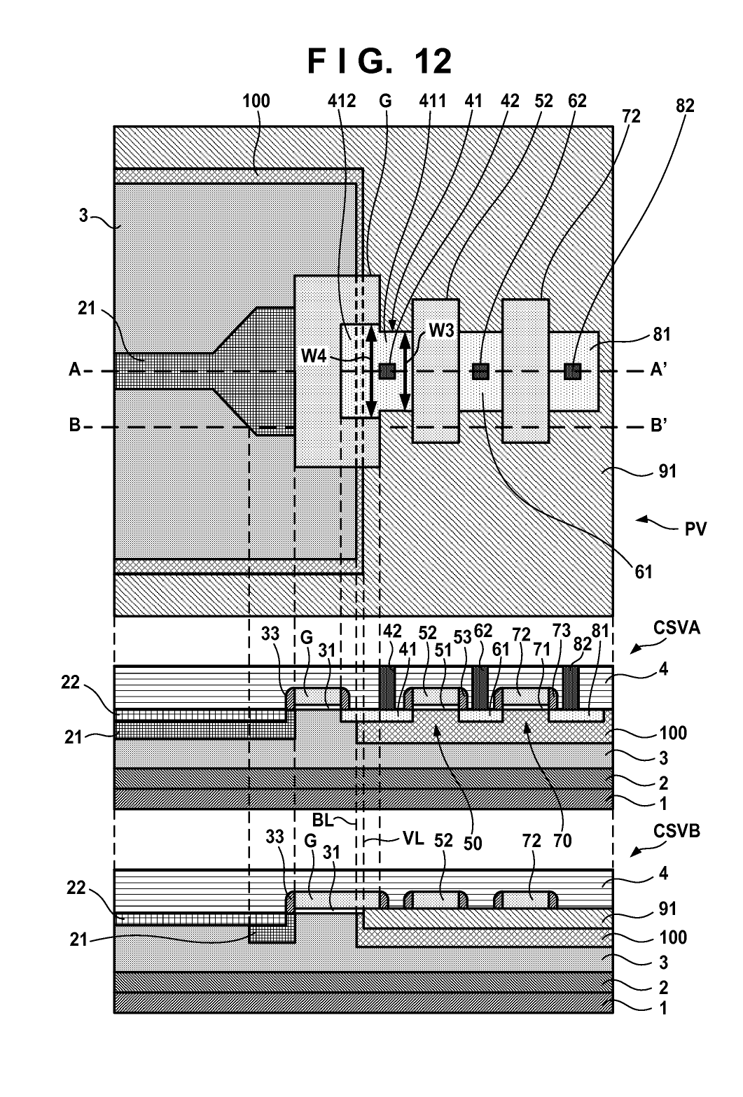

FIG. 12 shows a photoelectric conversion device according to the third embodiment of the present invention. FIG. 12 includes a plan view PV of the photoelectric conversion device, a sectional view CSVA taken along a line A-A′ of the plan view PV, and a sectional view CSVB taken along a line B-B′ line of the plan view PV. Note that for the sake of easy understanding of a structure, an interlayer insulating film 4, a third semiconductor region (surface region) 22, and a side spacer 33 are not shown in the plan view PV in FIG. 12. Note that matters not mentioned in the third embodiment can comply with those in the first and second embodiments. In the third embodiment, a floating diffusion region 41 includes a first diffusion region 411 and a second diffusion region 412 arranged between the first diffusion region 411 and gate electrode G. A width W4 of the second diffusion region 412 in a direction parallel to a virtual line VL is larger than a width W3 of the first diffusion region 411 in the direction parallel to the virtual line VL. Such an arrangement contributes to an increase in margin with respect to the misalignment of the charge accumulation region 21 relative to the gate electrode G in the direction parallel to the virtual line VL.

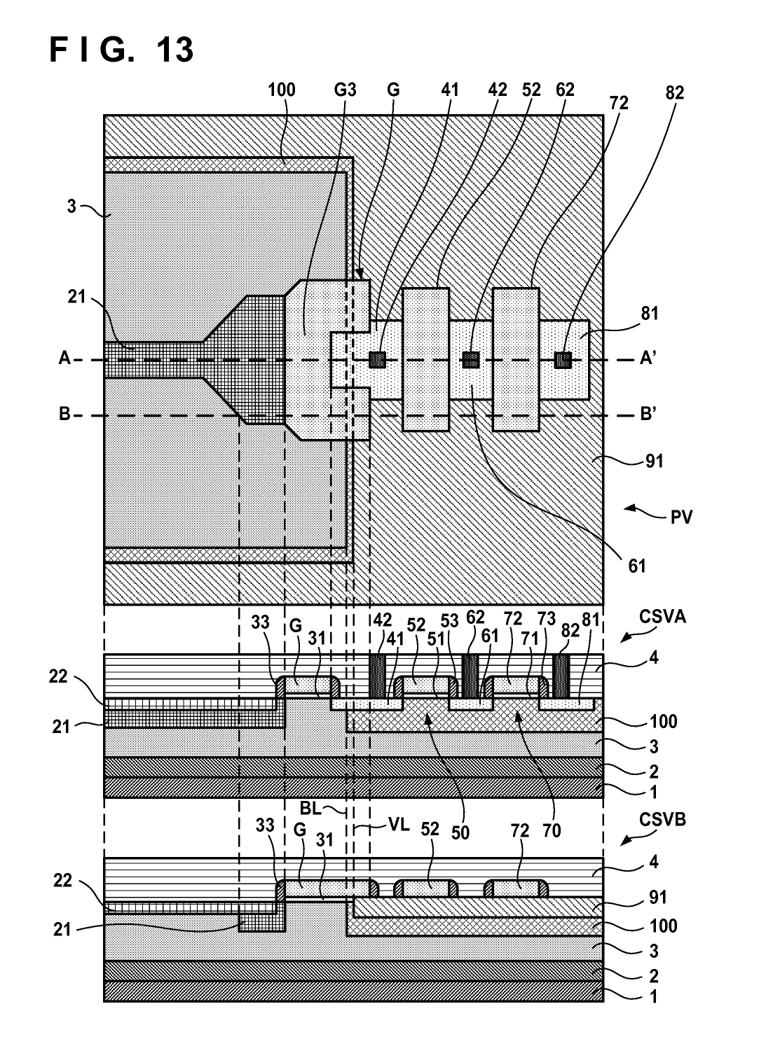

FIG. 13 shows a photoelectric conversion device according to the fourth embodiment of the present invention. FIG. 13 includes a plan view PV of the photoelectric conversion device, a sectional view CSVA taken along a line A-A′ of the plan view PV, and a sectional view CSVB taken along a line B-B′ line of the plan view PV. Note that for the sake of easy understanding of a structure, an interlayer insulating film 4, a third semiconductor region (surface region) 22, and a side spacer 33 are not shown in the plan view PV in FIG. 13. Note that matters not mentioned in the fourth embodiment can comply with those in the first to third embodiments. In the fourth embodiment, a third portion G3 of a gate electrode G has a portion whose width gradually decreases in a direction parallel to a virtual line VL with an increase in distance from a floating diffusion region 41. Such an arrangement is advantageous in reducing the capacitance of the gate electrode G and reducing load when driving the gate electrode G.

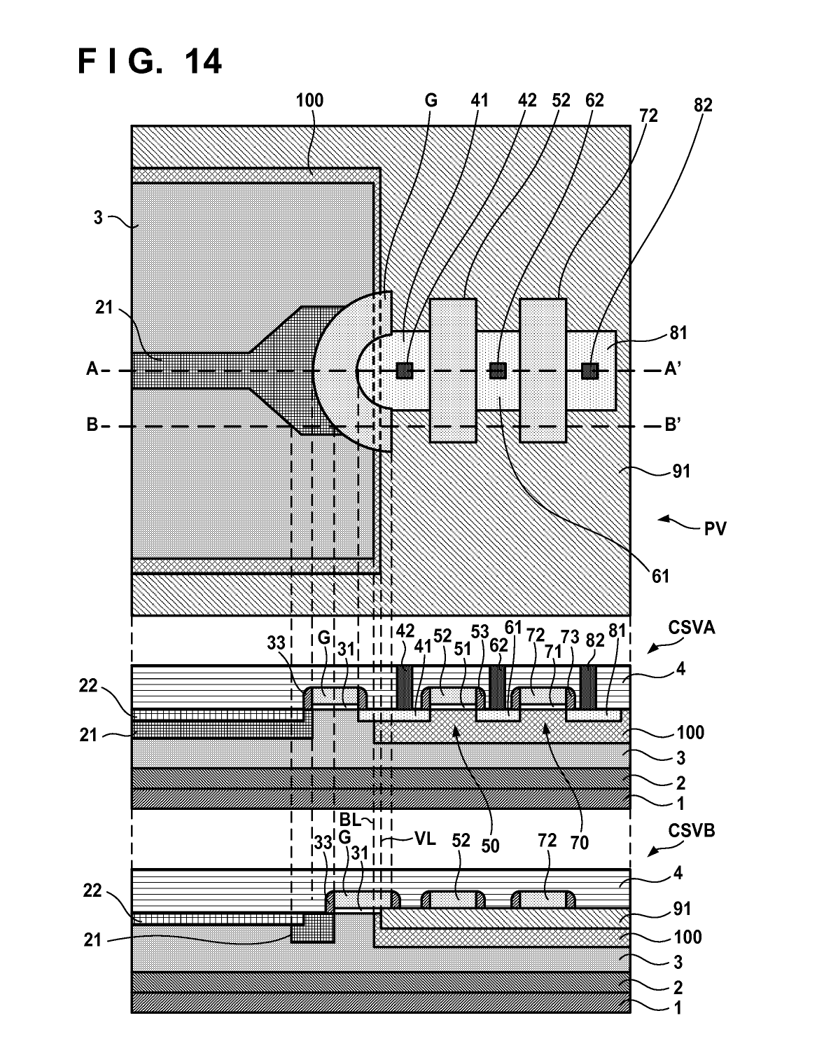

FIG. 14 shows a photoelectric conversion device according to the fifth embodiment of the present invention. FIG. 14 includes a plan view PV of the photoelectric conversion device, a sectional view CSVA taken along a line A-A′ of the plan view PV, and a sectional view CSVB taken along a line B-B′ line of the plan view PV. Note that for the sake of easy understanding of a structure, an interlayer insulating film 4, a third semiconductor region (surface region) 22, and a side spacer 33 are not shown in the plan view PV in FIG. 14. Note that matters not mentioned in the fifth embodiment can comply with those in the first to fourth embodiments. In the fifth embodiment, a gate electrode G (a portion including a first portion G1, a second portion G2, and a third portion G3 of the gate electrode G) has an arcuated shape. This arcuated shape has a center of curvature on the floating diffusion region 41 side. Such an arrangement is advantageous in equalizing the transfer length of charges (that is, the channel length) from a charge accumulation region 21 to the floating diffusion region 41 throughout the width of the gate electrode G or smoothing a change in the transfer length. This contributes to the stabilization of transfer characteristics.

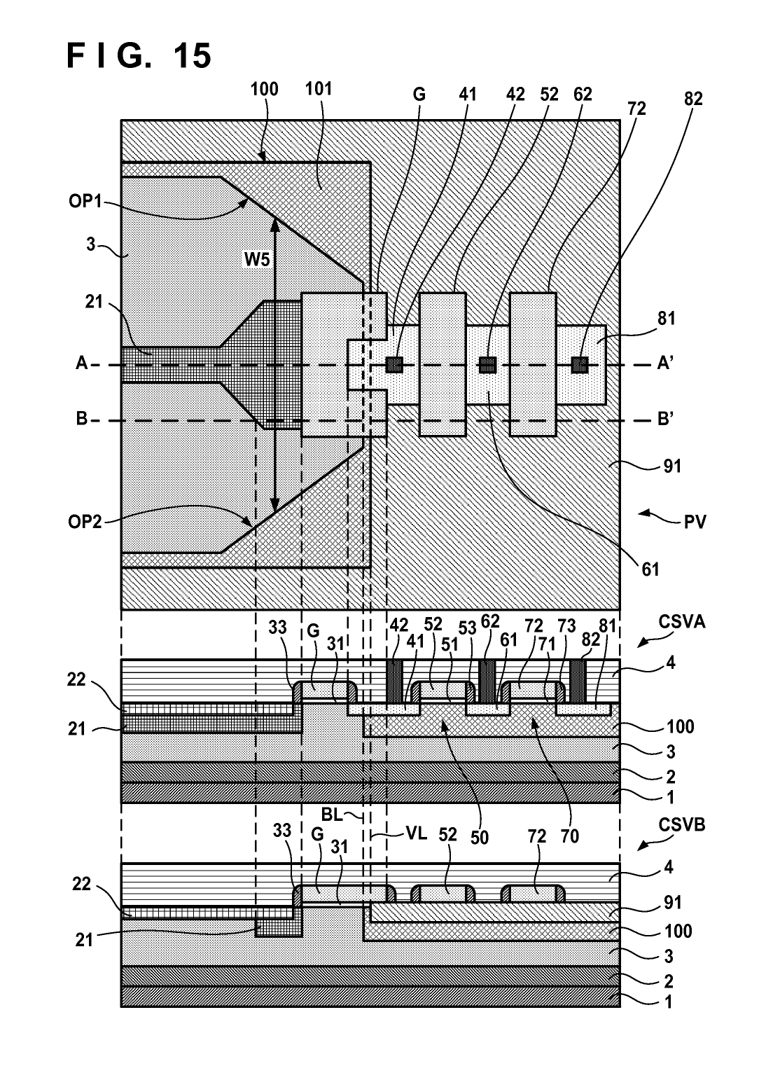

FIG. 15 shows a photoelectric conversion device according to the sixth embodiment of the present invention. FIG. 15 includes a plan view PV of the photoelectric conversion device, a sectional view CSVA taken along a line A-A′ of the plan view PV, and a sectional view CSVB taken along a line B-B′ line of the plan view PV. Note that for the sake of easy understanding of the structure, an interlayer insulating film 4, a third semiconductor region (surface region) 22, and a side spacer 33 are not shown in the plan view PV in FIG. 15. Note that matters not mentioned in the sixth embodiment can comply with those in the first to fifth embodiments. A portion 101 of an n-type first semiconductor region 100 which is arranged between a charge accumulation region 21 and an element isolation 91 so as to surround at least part of a p-type charge accumulation region 21 includes a pair of opposing portions OP1 and OP2 facing each other through the charge accumulation region 21. In this sixth embodiment, the first semiconductor region 100 includes a portion with an interval W5 between the pair of opposing portions OP1 and OP2 gradually decreasing toward a floating diffusion region 41. Such an arrangement decreases sensitivity but is advantageous in reducing a dark current.

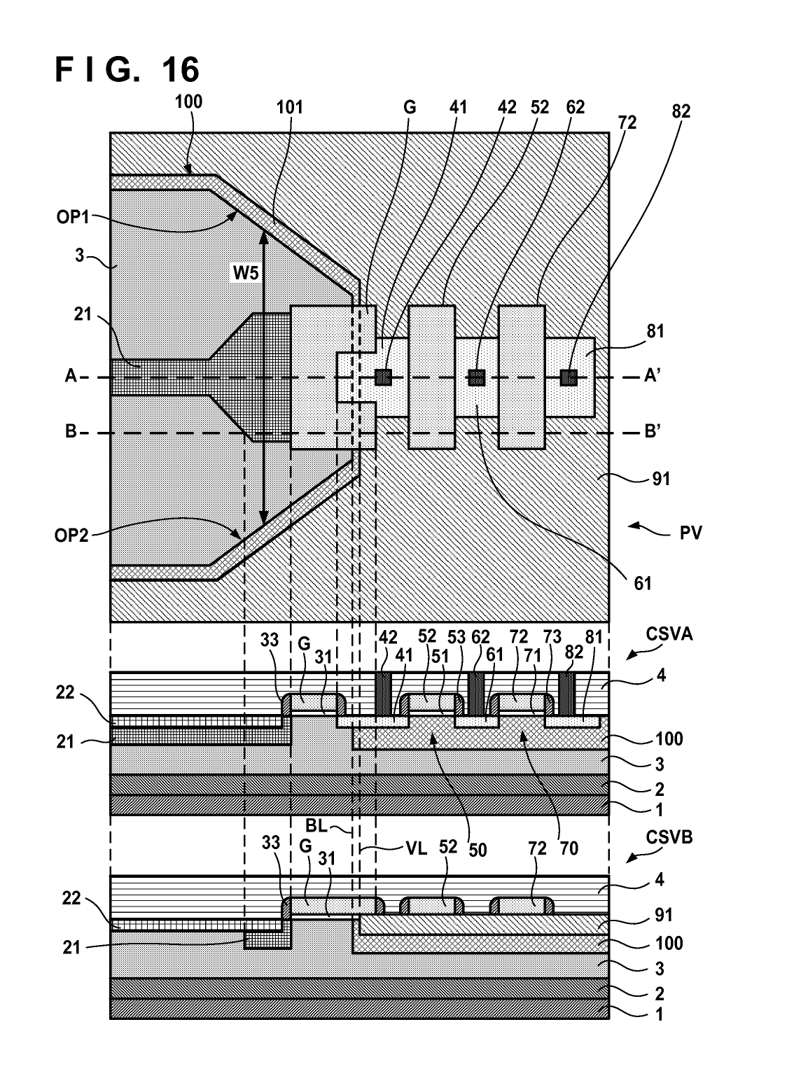

FIG. 16 shows a photoelectric conversion device according to the seventh embodiment of the present invention. FIG. 16 includes a plan view PV of the photoelectric conversion device, a sectional view CSVA taken along a line A-A′ of the plan view PV, and a sectional view CSVB taken along a line B-B′ line of the plan view PV. Note that for the sake of easy understanding of a structure, an interlayer insulating film 4, a third semiconductor region (surface region) 22, and a side spacer 33 are not shown in the plan view PV in FIG. 16. The seventh embodiment is a modification of the sixth embodiment. In the seventh embodiment, the shape of an element isolation 91 and an active region is defined in accordance with the shape of the portion with an interval W5 between a pair of opposing portions OP1 and OP2 gradually decreasing toward a floating diffusion region 41 in the sixth embodiment. In the seventh embodiment, since any active region which does not contribute to sensitivity can be removed, the degree of freedom in layout increases.

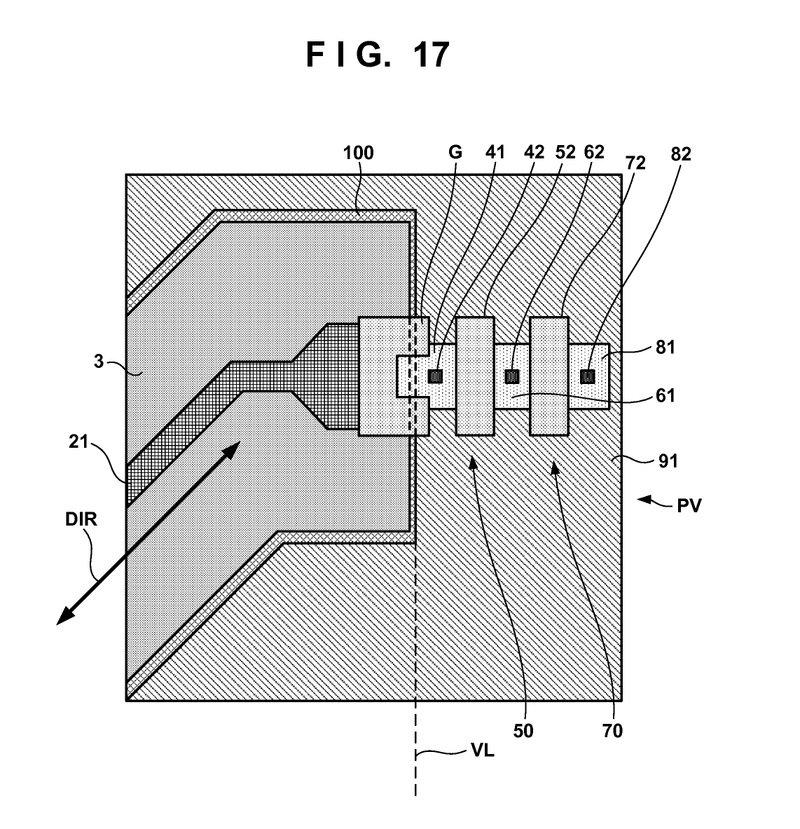

FIG. 17 shows a plan view PV of a photoelectric conversion device according to the eighth embodiment of the present invention. Note that for the sake of easy understanding of a structure, an interlayer insulating film 4, a third semiconductor region (surface region) 22, and a side spacer 33 are not shown in the plan view PV in FIG. 17. Note that matters not mentioned in the eighth embodiment can comply with those in the first to seventh embodiments. In the eighth embodiment, a first semiconductor region 100 and a charge accumulation region 21 have portions extending in a direction DIR obliquely intersecting a virtual line VL. In accordance with these portions, the third semiconductor region 22 (not shown) also has a portion extending in the direction DIR. The eighth embodiment can be applied to a line sensor having a plurality of photoelectric conversion units extending in the direction DIR obliquely intersecting the virtual line VL.

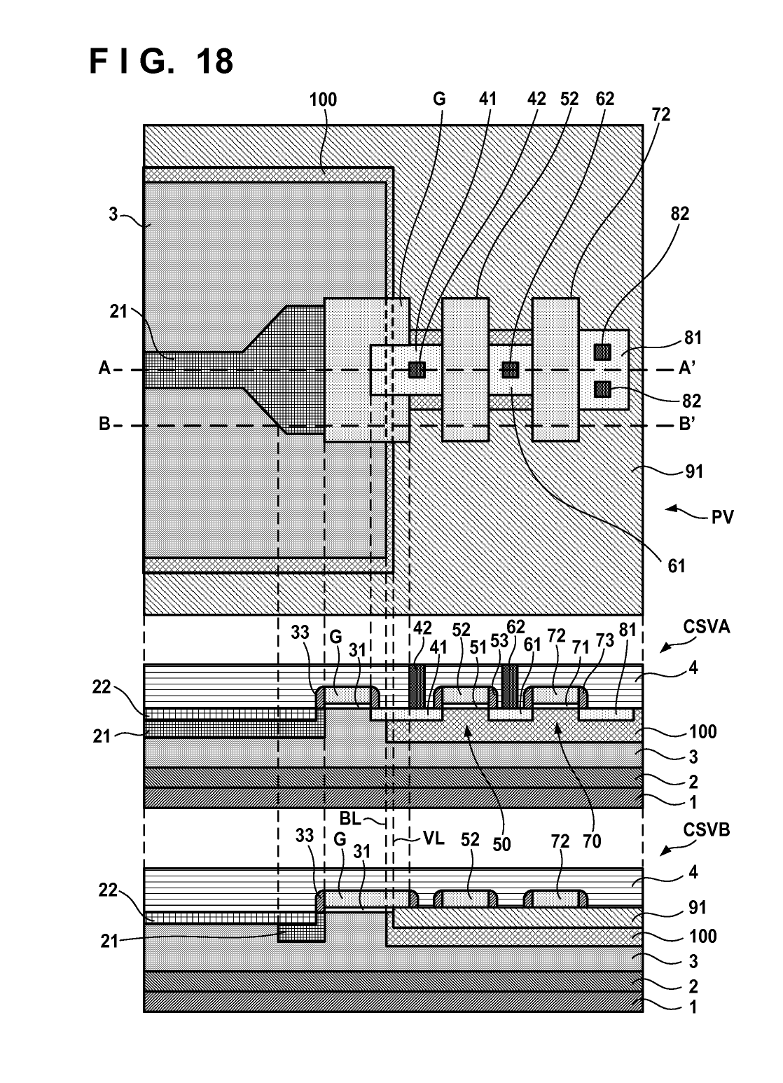

FIG. 18 shows a photoelectric conversion device according to the ninth embodiment of the present invention. FIG. 18 includes a plan view PV of the photoelectric conversion device, a sectional view CSVA taken along a line A-A′ of the plan view PV, and a sectional view CSVB taken along a line B-B′ line of the plan view PV. Note that for the sake of easy understanding of a structure, an interlayer insulating film 4, a third semiconductor region (surface region) 22, and a side spacer 33 are not shown in the plan view PV in FIG. 18. Note that matters not mentioned in the ninth embodiment can comply with those in the first to sixth embodiments. In the ninth embodiment, a floating diffusion region 41 and/or a diffusion region 61 is separated from an element isolation 91. According to the ninth embodiment, it is possible to reduce the dark current generated in the floating diffusion region 41 and/or the diffusion region 61. In this case, the diffusion region 61 is a region through which a signal goes. On the other hand, a diffusion region 81 may be in contact with the element isolation 91. The diffusion region 81 is, for example, a portion connected to a power supply voltage line and is a region through which no signal goes. Note that the diffusion region 81 may also be separated.

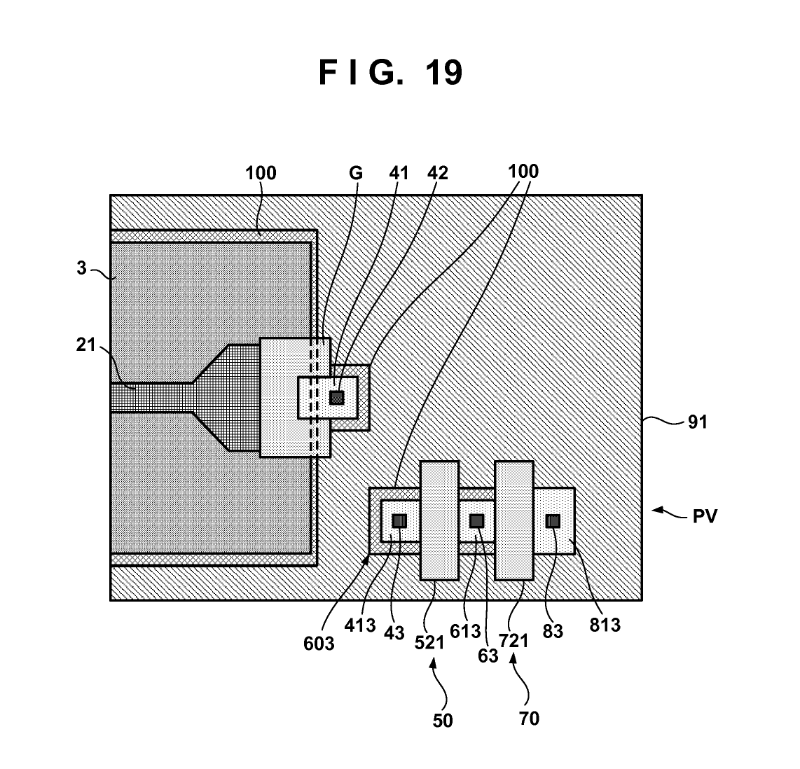

FIG. 19 shows a plan view PV of a photoelectric conversion device according to the 10th embodiment of the present invention. Note that for the sake of easy understanding of a structure, an interlayer insulating film 4, a third semiconductor region (surface region) 22, and a side spacer 33 are not shown in the plan view PV in FIG. 19. Note that matters not mentioned in the 10th embodiment can comply with those in the first to ninth embodiments. In the 10th embodiment, a MOS transistor 50 for sensitivity switching and a MOS transistor 70 for resetting are arranged in an active region 603 different from an active region where a photoelectric conversion unit and a floating diffusion region 41 are arranged. The MOS transistor 50 has a gate electrode 521 and forms a channel between a p-type diffusion region 413 and a p-type diffusion region 613. The MOS transistor 70 has a gate electrode 721 and forms a channel between the p-type diffusion region 613 and a p-type diffusion region 813. Contact plugs 43, 63, and 83 are respectively connected to the diffusion regions 413, 613, and 813.

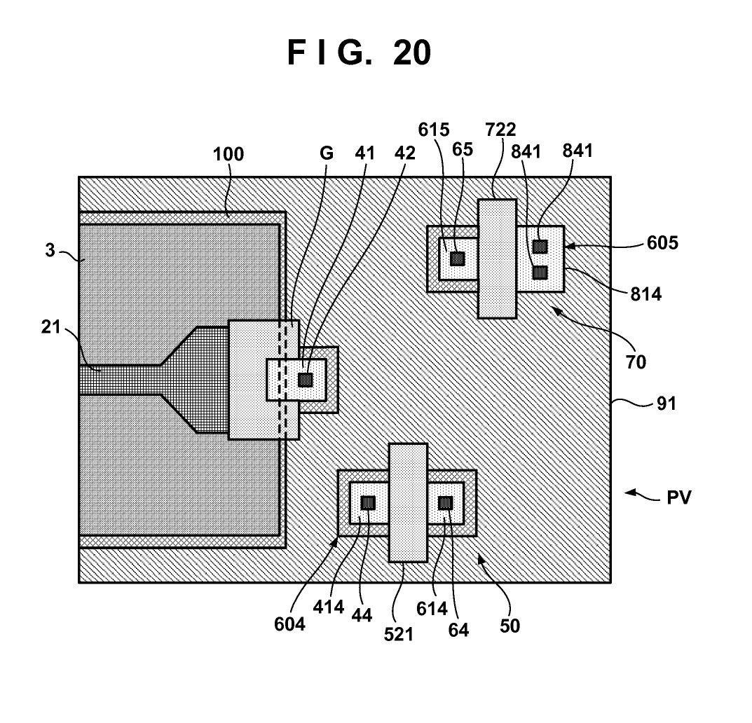

FIG. 20 shows a plan view PV of a photoelectric conversion device according to the 11th embodiment of the present invention. Note that for the sake of easy understanding of a structure, an interlayer insulating film 4, a third semiconductor region (surface region) 22, and a side spacer 33 are not shown in the plan view PV in FIG. 20. Note that matters not mentioned in the 11th embodiment can comply with those in the first to 10th embodiments. In the 11th embodiment, a MOS transistor 50 for sensitivity switching and a MOS transistor 70 for resetting are arranged in an active region 603 different from an active region where a photoelectric conversion unit and a floating diffusion region 41 are arranged. In addition, the MOS transistor 50 and the MOS transistor 70 for resetting are respectively arranged in a first active region 604 and a second active region 605 different from each other. The MOS transistor 50 has a gate electrode 521 and forms a channel between a p-type diffusion region 414 and a p-type diffusion region 614. The MOS transistor 70 has a gate electrode 722 and forms a channel between a p-type diffusion region 615 and a p-type diffusion region 814. Contact plugs 44, 64, 65, and 841 are respectively connected to the diffusion regions 414, 614, 615, and 814.

The arrangements of the respective embodiments described above can be changed and combined, as needed.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-140865, filed Jul. 8, 2014, which is hereby incorporated by reference herein in its entirety.

What is claimed is:

1. A photoelectric conversion device comprising:
an element isolation arranged to surround an active region including a first area and a second area which verge each other at a virtual line;
a charge accumulation region of a first conductivity type arranged in the first area;
a floating diffusion region of the first conductivity type arranged across the first area and the second area;
a gate electrode configured to form a channel for transferring charges accumulated in the charge accumulation region to the floating diffusion region; and
a first semiconductor region including a portion arranged between the charge accumulation region and the element isolation, so as to surround at least part of the charge accumulation region, and including a portion arranged in the second area, the first semiconductor region having a second conductivity type different from the first conductivity type,
wherein a width of the second area in a direction parallel to the virtual line is smaller than a width of the first area in the direction,
a boundary line defining an outer edge of the second area includes a first boundary line having a first point on the virtual line as one end and a second point which is not on the virtual line as the other end and a second boundary line having a third point on the virtual line as one end and a fourth point which is not on the virtual line as the other end,
the gate electrode includes a first portion spanning the first area and the second area so as to cover the first point, a second portion spanning the first area and the second area so as to cover the third point, and a third portion arranged above the first area so as to connect the first portion to the second portion, and
a boundary line defining an outer edge of the first semiconductor region includes a portion passing between the third portion and the virtual line.

2. The device according to claim 1, wherein the charge accumulation region, the floating diffusion region, and the first semiconductor region are arranged in a second semiconductor region of the second conductivity type,
an impurity concentration of the second conductivity type in the first semiconductor region is higher than an impurity concentration of the second conductivity type in the second semiconductor region, and
the channel is formed under the gate electrode in the second semiconductor region.

3. The device according to claim 2, wherein the second semiconductor region does not contact the element isolation.

4. The device according to claim 1, further comprising a third semiconductor region of the second conductivity type arranged on the charge accumulation region.

5. The device according to claim 4, wherein the third semiconductor region is arranged so as to contact the first semiconductor region in the first area.

6. The device according to claim 1, wherein the charge accumulation region is separated from the first semiconductor region in a direction parallel to the virtual line.

7. The device according to claim 6, wherein a width of the charge accumulation region in a direction parallel to the virtual line is smaller than a width of the gate electrode, within an area of the first area, in the direction parallel to the virtual line.

8. The device according to claim 5, wherein the charge accumulation region includes a first accumulation region and a second accumulation region arranged between the first accumulation region and the gate electrode, and
a width of the first accumulation region in a direction parallel to the virtual line is smaller than a width of the second accumulation region in the direction parallel to the virtual line.

9. The device according to claim 1, wherein the floating diffusion region includes a first diffusion region, and a second diffusion region arranged between the first diffusion region and the gate electrode, and
a width of the second diffusion region in a direction parallel to the virtual line is larger than a width of the first diffusion region in the direction parallel to the virtual line.

10. The device according to claim 1, wherein the first portion and the second portion extend in a direction perpendicular to the virtual line, and the third portion extends in a direction parallel to the virtual line.

11. The device according to claim 10, wherein the third portion has a portion whose width in a direction parallel to the virtual line decreases with an increase in distance from the floating diffusion region.

12. The device according to claim 1, wherein the gate electrode has an arcuated shape.

13. The device according to claim 1, wherein a portion arranged between the charge accumulation region and the element isolation so as to surround at least part of the charge accumulation region of the first semiconductor region includes a pair of opposing portions facing each other so as to sandwich the charge accumulation region, and the first semiconductor region includes a portion with an interval between the pair of opposing portions decreasing toward the floating diffusion region.

14. The device according to claim 13, wherein the first area has a portion whose width in a direction parallel to the virtual line gradually decreases toward the floating diffusion region.

15. The device according to claim 1, wherein the semiconductor region and the charge accumulation region have portions extending in a direction obliquely intersecting the virtual line.

16. The device according to claim 1, wherein the floating diffusion region does not contact the element isolation.

17. The device according to claim 1, further comprising a transistor configured to connect a capacitor to the floating diffusion region, the transistor being arranged in the active region.

18. The device according to claim 1, further comprising a first transistor configured to connect a capacitor to the floating diffusion region and a second transistor configured to reset a potential of the floating diffusion region,
the first transistor and the second transistor being arranged in the active region.

19. The device according to claim 1, further comprising a first transistor configured to connect a capacitor to the floating diffusion region and a second transistor configured to reset a potential of the floating diffusion region,
at least one of the first transistor and the second transistor being arranged in an active region separated from the active region.

20. The device according to claim 1, wherein the virtual line comprises a straight line.
